(19) United States
(12) Patent Application Publication
(10) Pub. No.: US 2019/0186725 A1
(43) Pub. Date: Jun. 20, 2019

(54) Universal Light Emitting Device

(71) Applicant: John Bryan Vincent, San Angelo, TX (US)

(72) Inventor: John Bryan Vincent, San Angelo, TX (US)

(21) Appl. No.: 15/478,469

(22) Filed: Apr. 4, 2017

(51) Int. Cl. F21V 23/02; F21V 17/00; F21V 19/00; F21V 23/04; F21V 3/00; H05K 1/18

(52) U.S. Cl. CPC F21V 23/02; F21V 17/002; F21V 19/0035; F21Y 2115/10; F21V 3/00; H05K 1/181; F21V 23/04

(57) ABSTRACT

A light emitting diode lighting device used for illumination specifically the illumination of commercial signage. The device has a modular housing and contains a printed circuit board, one or more light emitting diodes, and the wiring and power control circuitry to connect the device to an available power source. The devices can be wired together in a parallel circuit with another device creating a string of the LED devices. The device housing facilitates the addition of a colored lens that can change the color of the light emitted and the beam pattern of the emitted light. This device provides sign designers with an LED product that can produce light of varying intensity, color and beam angle by the manipulation of a single LED device.

### CROSS-REFERENCE TO RELATED APPLICATIONS

This application claims priority from a provisional application Ser. No. 62/317,955, filed on Apr. 4, 2016; hereby incorporated by reference in its entirety.

### STATEMENT REGARDING FEDERALLY SPONSORED RESEARCH DEVELOPMENT

Not Applicable

### THE NAMES OF THE PARTIES TO A JOINT RESEARCH AGREEMENT

Not Applicable

### INCORPORATION-BY-REFERENCE OF MATERIAL SUBMITTED ON A CD OR AS A TEXT FILE VIA THE OFFICE ELECTRONIC FILING SYSTEM (EFS-WEB)

Not Applicable

### STATEMENT REGARDING PRIOR DISCLOSURES BY THE INVENTOR OR JOINT INVENTOR

Not Applicable

### BACKGROUND OF THE INVENTION

The invention pertains to a universal lighting device that uses a light emitting diode (“LED”). The invention is capable of providing a range of light intensities, a range of beam patterns, and an array of colors. More particularly, the invention relates to an improved device for use in illuminated sign applications, specifically illuminated commercial signs. The invention provides sign makers and electricians a single universal LED product that is capable of meeting varied illumination needs for a myriad of different commercial sign applications.

Light-emitting devices containing light emitting elements such as Light Emitting Diodes (“LEDs”) are currently utilized in a range of lighting applications as an alternative or replacement to traditional lighting products, such as neon and fluorescent lamps that have previously been used extensively in the commercial sign industry. The in-situ lighting demands of the commercial sign industry vary greatly and depend upon a number of factors such as design preferences, location of the sign, size constraints of the sign or obstructions near the sign, and available distance from light source to sign face to evenly illuminate the face of the sign or material to be illuminated. LED replacement of previous lamp types in the commercial sign industry has been occurring over the past decade. The problem with the standard LED replacement is that the LED signage replacement products currently available emit light of a singular intensity. Because many commercial illuminated signs to be manufactured or retrofitted have unique dimensions the sign maker or electrician will have to test several different LED types of varying intensity and different spacing patterns of the LEDs to achieve both even lighting and the desired level of illumination on the face of the sign. Often times, in order to meet spacing requirements to provide even illumination across the sign face, the sign is too bright or intense, therefore requiring the use of one or more dimming modules typically places between the power source and the LED string. Dimming modules are expensive, increases installation times, often requires additional repeaters or amplifiers in multi-power supply situations, and are an additional point of failure. The present invention solves this problem by providing a single LED device that is capable of emitting a range of light intensities thereby by eliminating the need for a dimming system or the need of stocking multiple different intensity LED products. Additionally, the sign maker or electrician saves time in the manipulation of the LED spacing pattern for the desired level of illumination on the sign face.

This is of particular importance in commercial illuminated sign applications, where the type, size and depth of the sign, the substrate material type and opacity, and desired color rendering on the face of the sign varies dramatically. Currently, most LED devices used for these applications are of a fixed spacing, fixed light intensity, fixed light beam pattern, and fixed color. In most traditional sign applications the light emitting devices are in a string-like configuration where one of more LEDs are interconnected physically and electrically by one or more wires which serve to carry the power to each LED. The present invention allows the sign designer to use less LEDs more efficiently to achieve the desired level of illumination on the sign face.

Another limitation of current LED devices is the limited range of available colors. LEDs are monochromatic light sources, so the available color palette is limited by the available LED semiconducting materials. White LEDs are typically generated with a blue, violet, or UV light source that is coated with a phosphor material. The formulation of the phosphor allows for variation of the color temperature from a blue or cooler hue to a more yellow warmer hue. In either case the device output color is typically fixed. If there is a need to emit non-standard colors, typically “RGB” type LED devices are employed. This involves the use of color mixing by controlling the current to one or more red, blue, green, and sometimes amber or white LED chips or lamps on each device. These devices are typically more expensive, require four or more input wires, and must be controlled by a separate controller and/or repeaters which must be set exactly if the color is fixed. In addition to extra wiring, drivers and other costs, RGB systems are also problematic due to the fact that the different LED chips decay at different rates, resulting in uneven color shift over time. Currently LEDs are only capable of producing a limited number of colors of light from the LED without the use of an additional lens. The present invention allows the LED to produce an array of colors that currently cannot be produced by the LED alone. The invention does this by facilitating the attachment of an inexpensive removable transparent lens that covers the white LED. The transparent lens can be any color and therefore, acts as a filter to block the unwanted wavelengths allowing only the light wavelengths to pass that create the desired color.

With so many variables, product integrators need to regularly purchase and stock a wide range of different LEDs in order to meet the wide range of signage design requirements. This requires prototyping to determine the optimal light output, spacing and color rendering for a specific sign application. Typical surface mount LEDs used as light emitting elements on many light emitting devices typically have a Lambertian light intensity distribution with a typical beam angle of around 120°. Chip on board LED products also typically have a Lambertian type beam pattern as well. This creates specific challenges with product integrators, in particular sign manufacturers. Depending upon the depth of the sign and face material, the beam pattern can cause uneven illumination and spotting, the only remedy of which is to remove the devices after installation and use a device that incorporates a specialized optic to flatten the beam pattern. The only other choice may be to place the devices closer together, which requires more power, added cost, additional labor and may ultimately make the sign too bright. If the sign is too bright after the devices are installed, a separate dimmer must be added to the system. This creates added expense and in the event there are multiple power sources that are required as in larger signs or channel letters, the fabricator must add repeaters to ensure the dimming is consistent across the face of the sign. The removable transparent lenses of the present invention can alter the beam angle of the light emitted from the LED. In some cases, it may be desirable to place the LED modules along the side of the sign with the central beam pattern perpendicular to the LED face. In this situation, it is desirable to focus the beam to some angle less than 120 degrees to carry the light more evenly toward the center of the sign. Altering the beam angle of current LED replacement products is not possible unless the product has some structure to receive a lens covering the LED.

Finally, more and more applications require the need for solar power or simply need to minimize power during non-peak hours and there is not a simple and cost effective way to change the light output based upon the power requirements of the application. The present invention allows more flexibility in power management by providing a range of light intensities that consume varying amounts of power.

### BRIEF SUMMARY OF THE INVENTION

The present invention is an LED lighting device that is capable of a range of light intensities, a palette of light colors, and a range of emitted light beam angles. The device does this by a Printed Circuit Board (“PCB”) that contains two or more circuits capable of powering the LED. Each circuit within the PCB has unique impedance that determines the intensity of the emitted light from the LED depending on the circuit design. The color of the emitted light is altered by the addition of a colored transparent lens that alters the color of the emitted light. The transparent lens can also alter the beam angle of the emitted light depending on the geometry of the lens. The advantage of the present invention is the savings of time in sign design and cost savings by the elimination of keeping inventory of multiple LED types to create a specific intensity, color, or beam angle to achieve the desired illumination effect on the sign face due to the fact the present invention provides a range of light intensities, colors and beam angles from a single device.

### BRIEF DESCRIPTION OF THE SEVERAL VIEWS OF THE DRAWING(S)

FIG. 1—Top view of the PCB, LED, and bottom plate without the top box cover installed.

FIG. 2—Top view of the top box cover.

FIG. 3—Side view of top box cover.

FIG. 4—Top view of removable optical lens.

FIG. 5—Side view of removable lens.

FIG. 6—Perspective view of top box cover and PCB.

FIG. 7—Circuit diagram of the device.

### DETAILED DESCRIPTION OF THE INVENTION

An LED device allowing flexibility to meet the in-situ demands of the lighting application by providing a range of emitted light intensities, light colors and light beam patterns. Each device includes a housing made of a non-conductive material such as plastic, the housing contains a printed circuit board (“PCB”) and one or more Light Emitting Diodes (“LEDs”) attached to the PCB, as well as the electrical wiring to connect the device to a power source. Multiple devices can be connected in a parallel fashion, creating a string of LED devices. The printed circuit board has a negative connection and a minimum of two positive or vice-versa connections thereby creating at least three circuit combinations for powering the LED. Each circuit on the PCB contains at least one resistor and may contain multiple resistors in series to achieve the desired current to the LED or LEDs. Light emitting elements such as LEDs are current driven devices, therefore in the case of this type of light emitting element, the circuit and wiring configuration will determine the current supplied to each LED and therefore the corresponding light output and power consumption. The printed circuit board for the device is produced to facilitate the desired number of light intensities by inclusion of additional circuits on the PCB. The intensity of light emitted from the LED is determined by the circuits which are closed and providing power to the device. Power control circuitry is included to provide the required voltage to the invention.

The device also facilitates the attachment, to the device housing of an optic lens over the LED or LEDs contained in the device. This removable lens allows the color of the light emitted from the LED to be altered and also can be used to alter the beam angle of the light emitted either focusing or flattening the beam pattern. This removable lens can be temporarily attached to the device housing by a twist and lock or snap-fit construction of the lens; including but not limited to annular, cantilever, or torsional methods. The transparent lens may also be mechanically attached to the device housing by screws, glue or tape. These lenses are produced in multiple colors and lens geometries to alter the appearance of the light emitted from the device.

Adding additional positive connections and circuits to the PCB will simply increase the number of step gradient combinations between the lowest and highest light outputs predetermined by the PCB design. This feature enables the end user or product integrator the ability to choose a range of fixed light outputs and corresponding power consumption based upon the design characteristics of the application. This design also enables the use of simple switch-based control of the light output that does not require a separate dimmer. One or more simple switches can be wired between the power source and the circuit wires of the LED devices which can be switched manually or set on a timer or through an external control mechanism to change the output of the devices depending on the needs of the applications. Examples include dimming the lighting during non-peak business hours, the ability to flash the sign and end user preference of the desired brightness.

The transparent removable lens may incorporate one or more color changing materials which serve to change the color of the light emitted from the LEDs. The color changing materials include but are not limited to: a luminescent material such as a phosphor or a color filter such as a dye or pigment suspended in a plastic. Alternatively, the color changing materials may be incorporated into a separate film or polymer such as epoxy or a gel and placed over the light emitting element to alter the light emitted from the light emitting element without the removable lens. The cover may further be placed on top of the colored film or polymer in a sandwich type configuration.

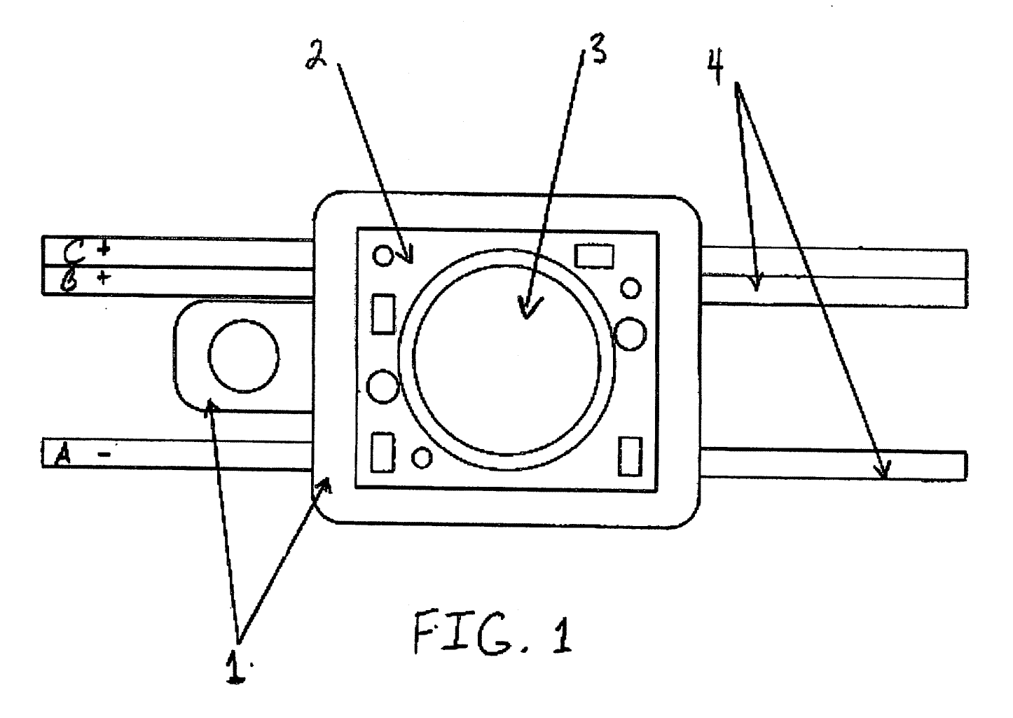

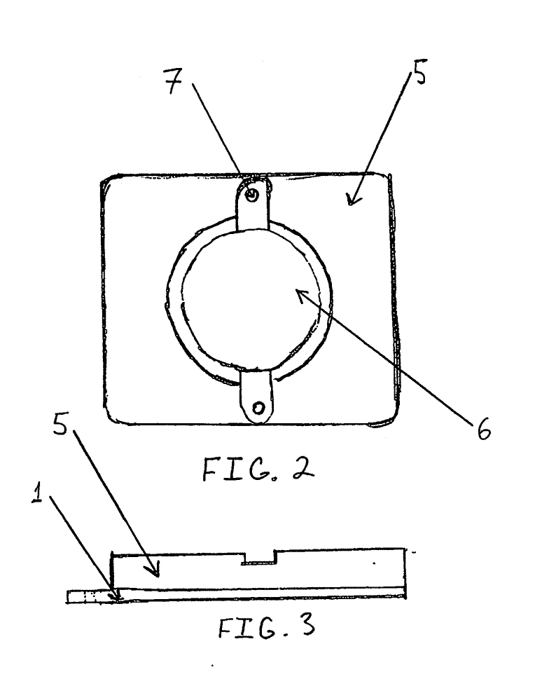

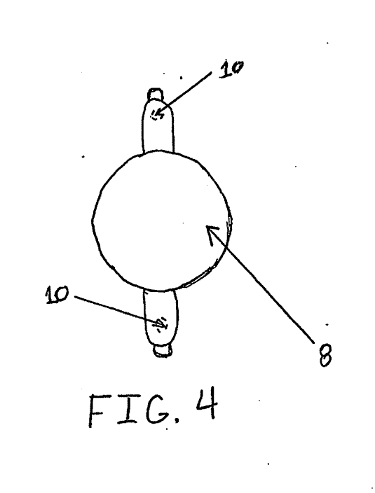

The best mode of the invention includes a rectangular plastic housing that is eight tenths of an inch by nine tenths of an inch and approximately three tenths of an inch thick. The housing is a two part assembly containing a back plate, 1 FIGS. 1 and 3, and top box cover, 5 FIGS. 2, 3 and 6; that fit together to house the PCB and LED and may be mechanically attached in separate parts or over-molded in a single part. The top box cover of the housing has three small circular openings on opposite sides of the box cover to facilitate the entry and exit of the electrical wires, 4 FIG. 1, from the device housing to power the LED. The electrical wires connect to a power source such as a low voltage power supply or in the event of an AC LED directly to the primary circuit power.

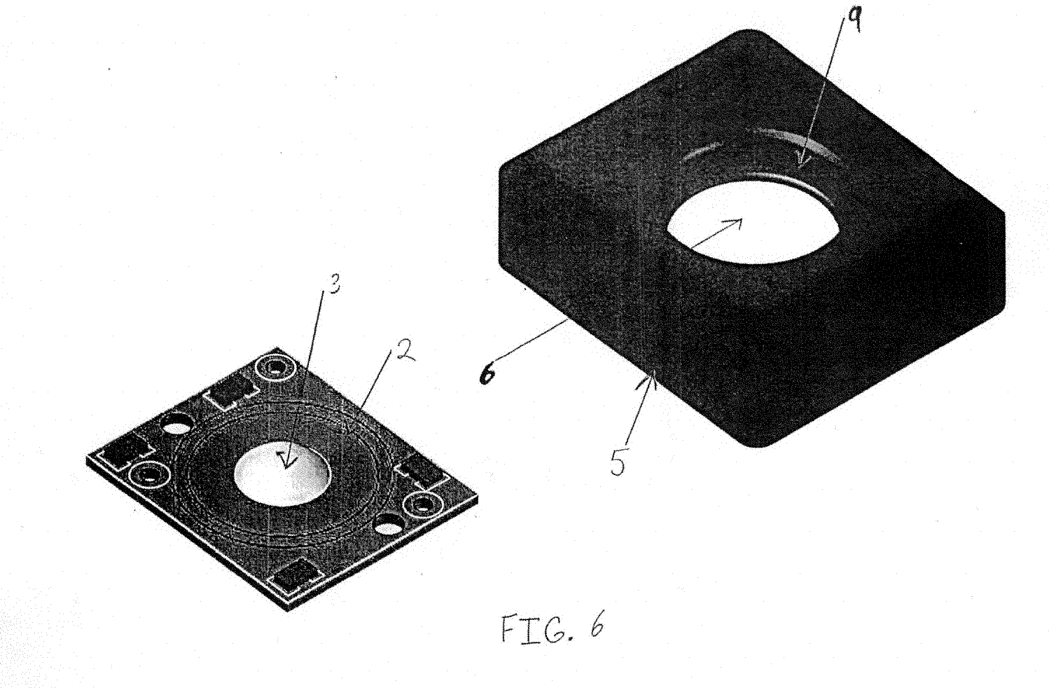

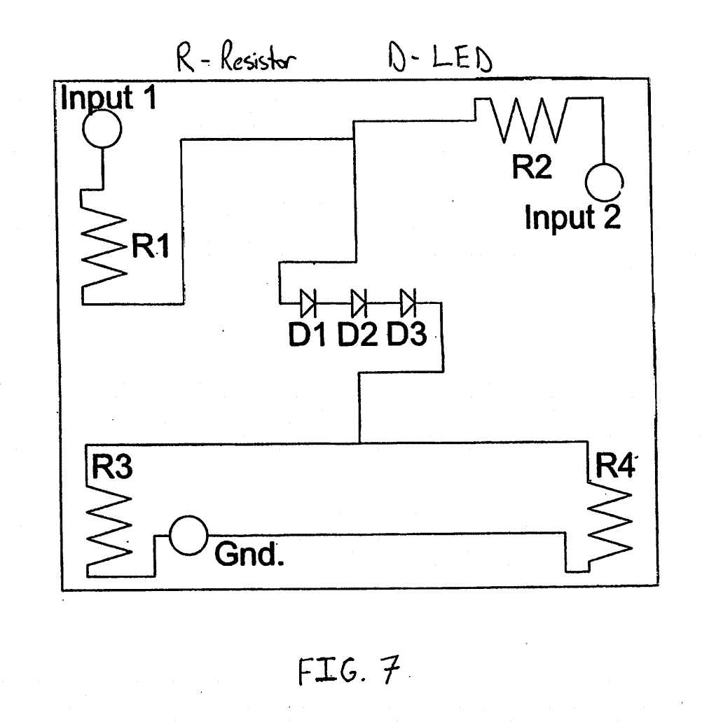

The back plate has the same side lengths as the top box cover so that back plate and top cover are flush on all sides except one where the back plate has a small ear with a hole through it for attaching the housing to a surface by screw or nail. The back plate also comes with an adhesive tape on the outer side of the back plate to attach the device to a sign or other surface. The top box cover has a depression in the center of the outer face of the top box cover, 9 FIG. 6. At the center of this depression on the top cover is a small opening that allows for only the light emitting portion of the LED to be exposed to the exterior of the device housing, 6 FIGS. 2 and 6. The top box cover also has two circular depressions on opposite edges of the top box cover that facilitate the snap on connection of the removable lenses, 7 FIG. 2.

Mounted inside the device housing is the PCB, 2 FIGS. 1 and 6, with an LED 3 FIGS. 1 and 6, or multiple LEDs electrically connected to the PCB. The plurality of LEDs may be surface mount through hole, or chip on board design. Each circuit on the PCB contains at least one resistor and may contain multiple resistors and contains at least one LED and may contain multiple LEDs, FIG. 7. The housing protects the electrical connections, PCB and LED from moisture and exposure to ambient conditions while the device is in operation. There are multiple LED chips that can be used in the preferred embodiment of the invention. These include: a UV or blue LED with a phosphor that can be formulated to produce white light varying from 2500K-12000K (“white LED”), as well as any monochromatic LED such as red, blue, green, orange, amber, etc. These different LEDs produce color of light as indicated and all may be used in addition to the removable lenses. The white LED is used when using the additional removable colored lenses. However, clear lens may be used with both the white LEDs or with monochromatic LEDs to simply change the beam pattern of the LED lamp or chip. Additionally, the LED lens may be colored and have a lens geometry that changes the beam pattern of the LED for use with the white LEDs.

The PCB has a negative connection and two positive connections or vice versa to close the electrical circuit. Referring to FIG. 1 the negative wire is referred to as wire A and the positive wires are wire B for low light intensity output and Wire C for medium light intensity output. As an example of the device's operation, if wire B is connected to the power source to close the circuit with wire A, the current supplied to the LED would be low and the corresponding light output and power consumption would be low. If wire C is connected to the power source to close the circuit with wire A, the current supplied to the LED would be medium and the corresponding light output and power consumption would be medium. If Wire B and C are both connected to the power source to close the circuit with wire A, the current supplied to the LED would be high and the corresponding light output and power consumption would be high.

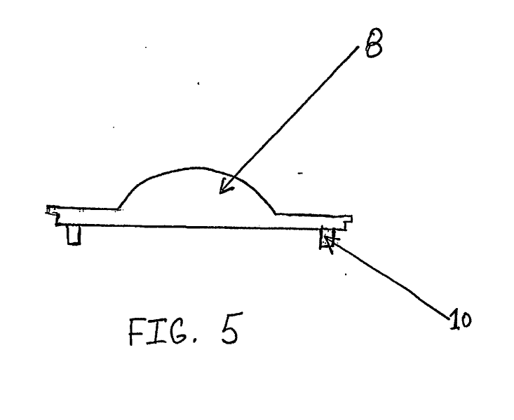

The transparent lenses, 8 FIGS. 4 and 5, can accommodate any color light desired by the addition of a colored transparent plastic lens that covers the LED. The lens is also capable of altering the beam pattern of the light emitted depending on the geometry of the transparent plastic lens. These lenses may be supplied in any color the end user desires. The plastic lenses have a winged design with two small circular protrusions on near the end of the lens wings, 10 FIGS. 4 and 5. These circular protrusions snap into the circular depressions on the exterior face of the top box housing thereby securing the lens

It is to be understood that the present invention is not limited to the embodiments described above, but encompasses any and all embodiments within the scope of the following claims. Immaterial modifications may be made to the embodiments described here without departing from what is claimed.

### SEQUENCE LISTING

Not Applicable

1. A light emitting device comprised of, a housing that encapsulates a printed circuit board and one or more light emitting diodes, the light emitting diode or diodes are exposed through holes in the housing to the exterior of the housing, the printed circuit board has two or more circuits, each circuit having a different impedance and one or more light emitting diodes electrically connected to the circuit board and the circuit board is connected by wires to an electrical power source.

2. A light emitting device consisting of, a housing that encapsulates a printed circuit board and one or more light emitting diodes, the light emitting diode or diodes are exposed through holes in the housing to the exterior of the housing, the printed circuit board has a two or more circuits, each having a different impedance and one or more light emitting diodes electrically connected to the circuit board and the circuit board is connected by wires to an electrical power source.

3. A device according to claim 1 where two or more of the devices are connected to a power source in a parallel circuit.

4. A device according to claim 1 where the power source is a battery or solar cell.

5. A device according to claim 1 where each circuit on the PCB has a switch to open or close the circuit.

6. A device according to claim 1 where the housing is designed to receive an optical lens that covers the light emitting diode or diodes.

7. A device according to claim 6 where the optical lens removable.

8. A device according to claim 6 where the optical lens is colored.

9. A device according to claim 6 where the optical lens is colored and removable.

10. A device according to claim 2 where two or more of the devices are connected to a power source in a parallel circuit.

11. A device according to claim 2 where the power source is a battery or solar cell.

12. A device according to claim 2 where each circuit on the PCB has a switch to open or close the circuit.

13. A device according to claim 2 where the housing is designed to receive an optical lens that covers the light emitting diode or diodes.

14. A device according to claim 13 where the optical lens is removable.

15. A device according to claim 13 where the optical lens is colored.

16. A device according to claim 13 where the optical lens is colored and removable.
